(19) United States
(12) Patent Application Publication
(10) Pub. No.: US 2024/0338149 A1
(43) Pub. Date: Oct. 10, 2024

(54) SCHEDULING FOR MEMORY

(71) Applicant: Micron Technology, Inc., Boise, ID (US)

(72) Inventors: Chun-Yi Liu, Rancho Cordova, CA (US); Ameen D. Akel, Rancho Cordova, CA (US); Lance P. Johnson, Saint Paul, MN (US)

(21) Appl. No.: 18/607,283

(22) Filed: Mar. 15, 2024

Related U.S. Application Data
(60) Provisional application No. 63/457,703, filed on Apr. 6, 2023.

(51) Int. Cl. G06F 3/06

(52) U.S. Cl. CPC G06F 3/0659; G06F 3/0619; G06F 3/0673

(57) ABSTRACT

Methods, systems, and devices for schedule memory are described. Specifically, techniques are described for a memory interface between a host system and memory (e.g., a tightly coupled memory). For example, a memory interface block (MIB) between the host system and the memory system may schedule access operations performed by the memory system, schedule and perform error control operations, schedule and perform media management operations, as well as schedule and perform other operations. The use of such a MIB may enable the improvement of the memory system by reducing latency and increasing efficiency of memory accesses, while reducing impacts on the architecture and design of the host system.

### CROSS REFERENCE

The present application for patent claims the benefit of U.S. Provisional Patent Application No. 63/457,703 by LIU et al., entitled “SCHEDULING FOR MEMORY,” filed Apr. 6, 2023, assigned to the assignee hereof, and expressly incorporated by reference in its entirety herein.

### TECHNICAL FIELD

The following relates to one or more systems for memory, including scheduling for memory.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not- and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source.

### BRIEF DESCRIPTION OF THE DRAWINGS

FIGS. 1 and 2 show examples of systems that support scheduling for memory in accordance with examples as disclosed herein.

FIGS. 3A, 3B, and 3C show examples of devices that support scheduling for memory in accordance with examples as disclosed herein.

FIG. 4 shows an example of a system that supports scheduling for memory in accordance with examples as disclosed herein.

FIG. 5 shows an example of a flowchart that supports scheduling for memory in accordance with examples as disclosed herein.

FIG. 6 shows a block diagram of a memory system that supports scheduling for memory in accordance with examples as disclosed herein.

FIG. 7 shows a flowchart illustrating a method or methods that support scheduling for memory in accordance with examples as disclosed herein.

### DETAILED DESCRIPTION

Memory systems may be configured to provide an efficient and high-performance based solution for memory-centric logic, such as graphics processing units (GPUs). In some examples, these memory systems may include tightly coupled dynamic random access memory (TCDRAM). The TCDRAM may be closely coupled (e.g., physically coupled) with the GPU as part of the physical memory map of the memory system. The TCDRAM, unlike cache-based memory, may not be backed by a level of external memory with the same physical addresses. Instead, the TCDRAM may be associated with and located within a dedicated base address, where each portion of the TCDRAM may be non-overlapping within the address.

The utilization of TCDRAM may reduce latency in memory accesses by avoiding the use of memory caches and thus the unpredictability of access time related to the use of caches. That is, because code is not initially fetched from a cache or other external memory at the start of an access operation, the GPU (e.g., or other processing unit) may have immediate access to the associated memory system which may result in improved access latency. While the memory system may enable efficient memory accesses and other processes due to this close relationship with the associated GPU of the memory system, it may be useful to have and incorporate a memory interface architecture that enables higher performance.

Techniques are described for a memory interface between a host system (e.g., a GPU) and a memory system (e.g., TCDRAM). For example, a memory interface block (MIB) between the host system and the memory system may schedule access operations performed by the memory system, schedule error control operations, schedule media management operations, as well as schedule other operations. In some examples, the MIB may be located on a die of the host system. The MIB may allow for improved access operation latency by assisting (e.g., collaborating with) one or more memory controllers of the host system die on various scheduling operations. For example, the MIB may schedule operations traditionally performed by the host system. That is, the MIB may schedule error control operations, schedule media management operations, schedule test engines, and/or may improve logic-to-memory I/O, among others.

In some examples, the MIB may also assist in controlling the flow of commands to and from each of the memory banks. For example, each of the banks may be coupled with and share one or more channels configured to communicate data, C/A, and clock information with the memory die. Rather than leave the management of efficient sharing of these channels to the host system, the MIB may control the flow of data and commands over each of the channels between the host system die and the banks. As such, the use of the MIB may enable the improvement of the memory system by reducing latency and increasing efficiency of memory accesses, while reducing impacts on the architecture and design of the host system.

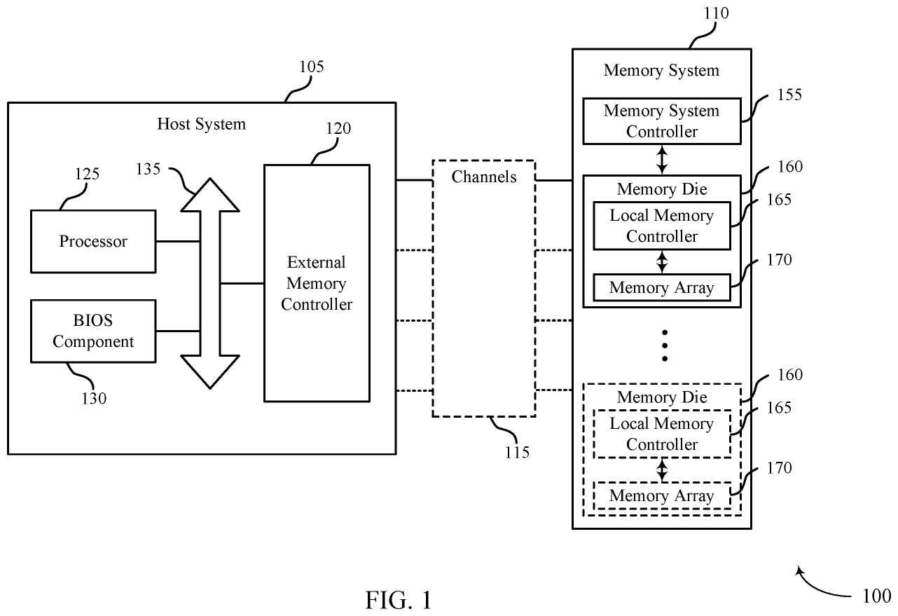

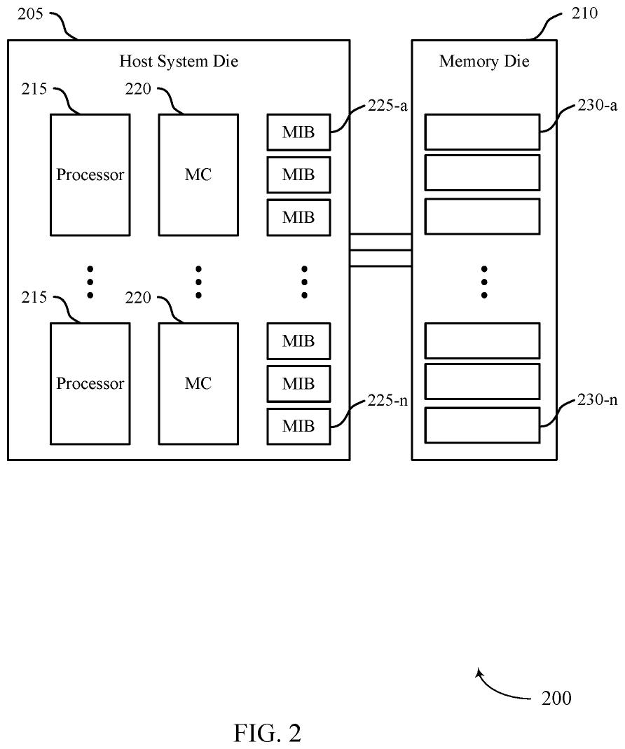

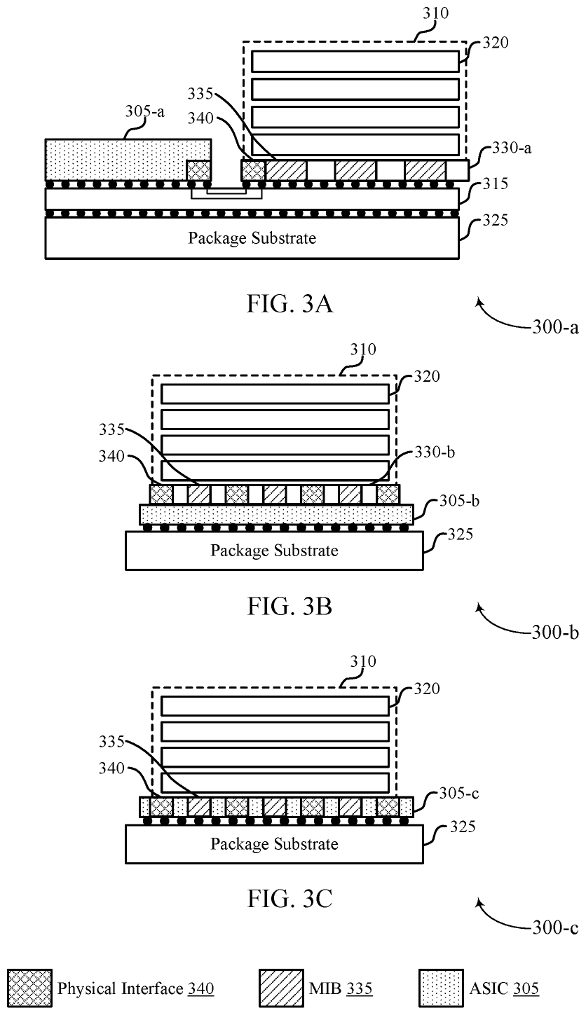

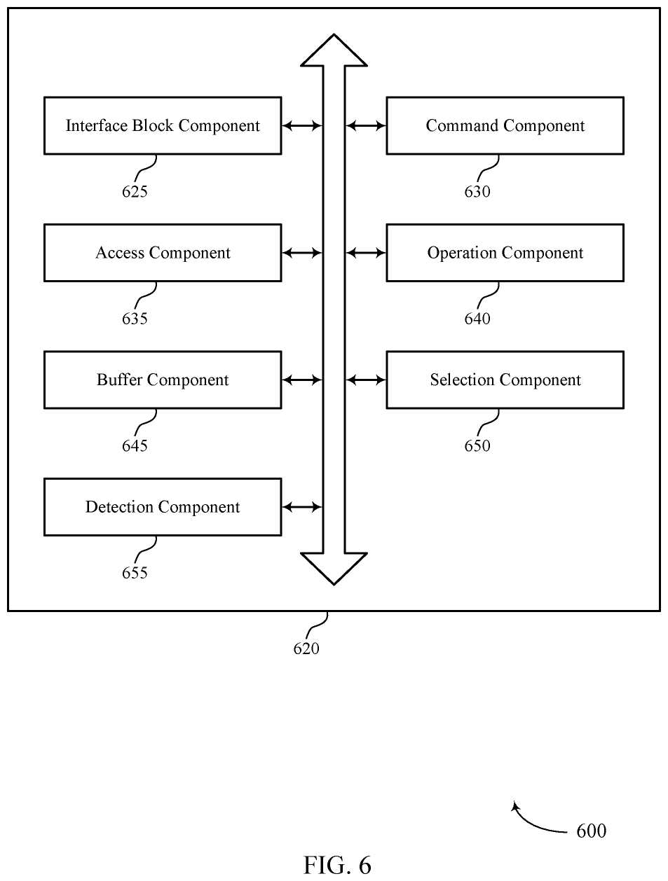

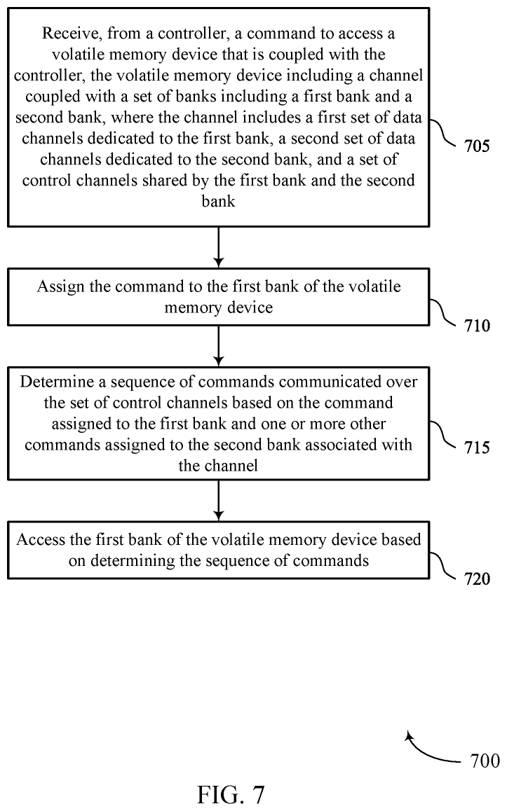

Features of the disclosure are initially described in the context of systems as described with reference to FIGS. 1 and 2. Features of the disclosure are described in the context of devices, systems, and flowcharts as described with reference to FIGS. 3A through 5. These and other features of the disclosure are further illustrated by and described with reference to an apparatus diagram and flowcharts that relate to scheduling for memory as described with reference to FIGS. 6 and 7.

FIG. 1 shows an example of a system 100 that supports scheduling for memory in accordance with examples as disclosed herein. The system 100 may include portions of an electronic device, such as a computing device, a mobile computing device, a wireless communications device, a graphics processing device, a vehicle, or other systems. The system 100 includes a host system 105, a memory system 110, and one or more channels 115 coupling the host system 105 with the memory system 110 (e.g., to provide a communicative coupling). The system 100 may include one or more memory systems 110, but aspects of the one or more memory systems 110 may be described in the context of a single memory system 110.

The host system 105 may be an example of a processor (e.g., circuitry, processing circuitry, a processing component) that uses memory to execute processes, such as a processing system of a computing device, a mobile computing device, a wireless communications device, a graphics processing device, a wearable device, an internet-connected device, a vehicle controller, a system on a chip (SoC), or other stationary or portable electronic device, among other examples. The host system 105 may include one or more of an external memory controller 120, a processor 125, a basic input/output system (BIOS) component 130, or other components (e.g., a peripheral component, an input/output controller, not shown). The components of the host system 105 may be coupled with one another using a bus 135.

An external memory controller 120 may be configured to enable communication of information (e.g., data, commands, control information, configuration information) between components of the system 100 (e.g., between components of the host system 105, such as the processor 125, and the memory system 110). An external memory controller 120 may process (e.g., convert, translate) communications exchanged between the host system 105 and the memory system 110. In some examples, an external memory controller 120, or other component of the system 100, or associated functions described herein, may be implemented by or be part of the processor 125. For example, an external memory controller 120 may be hardware, firmware, or software (e.g., instructions), or some combination thereof implemented by a processor 125 or other component of the system 100 or the host system 105. Although an external memory controller 120 is illustrated outside the memory system 110, in some examples, an external memory controller 120, or its functions described herein, may be implemented by one or more components of a memory system 110 (e.g., a memory system controller 155, a local memory controller 165) or vice versa. In various examples, the host system 105 or an external memory controller 120 may be referred to as a host.

A processor 125 may be operable to provide functionality (e.g., control functionality) for the system 100 or the host system 105. A processor 125 may be a general-purpose processor, a digital signal processor (DSP), an application-specific integrated circuit (ASIC), a field-programmable gate array (FPGA) or other programmable logic device, discrete gate or transistor logic, discrete hardware components, or any combination thereof. In some examples, a processor 125 may be an example of a central processing unit (CPU), a graphics processing unit (GPU), a general-purpose GPU (GPGPU), or an SoC, among other examples.

In some examples, the system 100 or the host system 105 may include an input component, an output component, or a combination thereof. Input components may include a sensor, a microphone, a keyboard, another processor (e.g., on a printed circuit board), an interface (e.g., a user interface, an interface between other devices), or a peripheral that interfaces with system 100 via one or more peripheral components, among other examples. Output components may include a display, audio speakers, a printing device, another processor on a printed circuit board, or a peripheral that interfaces with the system 100 via one or more peripheral components, among other examples.

The memory system 110 may be a component of the system 100 that is operable to provide physical memory locations (e.g., addresses) that may be used or referenced by the system 100. The memory system 110 may include a memory system controller 155 and one or more memory dies 160 (e.g., memory chips) to support a capacity for data storage. The memory system 110 may be configurable to work with one or more different types of host systems 105, and may respond to and execute commands provided by the host system 105 (e.g., via an external memory controller 120). For example, the memory system 110 (e.g., a memory system controller 155) may receive a write command indicating that the memory system 110 is to store data received from the host system 105, or receive a read command indicating that the memory system 110 is to provide data stored in a memory die 160 to the host system 105, or receive a refresh command indicating that the memory system 110 is to refresh data stored in a memory die 160, among other types of commands and operations.

A memory system controller 155 may include components (e.g., circuitry, logic) operable to control operations of the memory system 110. A memory system controller 155 may include hardware, firmware, or instructions that enable the memory system 110 to perform various operations, and may be operable to receive, transmit, or execute commands, data, or control information related to operations of the memory system 110. A memory system controller 155 may be operable to communicate with one or more of an external memory controller 120, one or more memory dies 160, or a processor 125. In some examples, a memory system controller 155 may control operations of the memory system 110 in cooperation with a local memory controller 165 of a memory die 160.

Each memory die 160 may include a local memory controller 165 and a memory array 170. A memory array 170 may be a collection of memory cells, with each memory cell being operable to store one or more bits of data. A memory die 160 may include a two-dimensional (2D) array of memory cells, or a three-dimensional (3D) array of memory cells. In some examples, a 2D memory die 160 may include a single memory array 170. In some examples, a 3D memory die 160 may include two or more memory arrays 170, which may be stacked or positioned beside one another (e.g., relative to a substrate).

A local memory controller 165 may include components (e.g., circuitry, logic) operable to control operations of a memory die 160. In some examples, a local memory controller 165 may be operable to communicate (e.g., receive or transmit data or commands or both) with a memory system controller 155. In some examples, a memory system 110 may not include a memory system controller 155, and a local memory controller 165 or an external memory controller 120 may perform various functions described herein. As such, a local memory controller 165 may be operable to communicate with a memory system controller 155, with other local memory controllers 165, or directly with an external memory controller 120, or a processor 125, or any combination thereof. Examples of components that may be included in a memory system controller 155 or a local memory controller 165 or both may include receivers for receiving signals (e.g., from the external memory controller 120), transmitters for transmitting signals (e.g., to the external memory controller 120), decoders for decoding or demodulating received signals, encoders for encoding or modulating signals to be transmitted, sense components for sensing states of memory cells of a memory array 170, write components for writing states to memory cells of a memory array 170, or various other components operable for supporting described operations of a memory system 110.

A host system 105 (e.g., an external memory controller 120) and a memory system 110 (e.g., a memory system controller 155) may communicate information (e.g., data, commands, control information, configuration information) using one or more channels 115. Each channel 115 may be an example of a transmission medium that carries information, and each channel 115 may include one or more signal paths (e.g., a transmission medium, an electrical conductor, an electrically conductive path) between terminals associated with the components of the system 100. For example, a channel 115 may be associated with a first terminal (e.g., including one or more pins, including one or more pads) at the host system 105 and a second terminal at the memory system 110. A terminal may be an example of a conductive input or output point of a device of the system 100, and a terminal may be operable to act as part of a channel 115. In some implementations, at least the channels 115 between a host system 105 and a memory system 110 may include or be referred to as a host interface (e.g., a physical host interface). In some implementations, a host interface may include or be associated with interface circuitry (e.g., signal drivers, signal latches) at the host system 105 (e.g., at an external memory controller 120), or at the memory system 110 (e.g., at a memory system controller 155), or both.

In some examples, a channel 115 (e.g., associated signal paths and terminals) may be dedicated to communicating one or more types of information. For example, the channels 115 may include one or more command and address channels, one or more clock signal channels, one or more data channels, among other channels or combinations thereof. In some examples, signaling may be communicated over the channels 115 using single data rate (SDR) signaling or double data rate (DDR) signaling. In SDR signaling, one modulation symbol (e.g., signal level) of a signal may be registered for each clock cycle (e.g., on a rising or falling edge of a clock signal). In DDR signaling, two modulation symbols of a signal may be registered for each clock cycle (e.g., on both a rising edge and a falling edge of a clock signal).

In some examples, one or more of the channels 115 may include one or more error detection code (EDC) channels. The EDC channels may be operable to communicate error detection signals, such as checksums, to improve system reliability. An EDC channel may include any quantity of signal paths.

In some examples, a memory interface between the host system 105 (e.g., a GPU) and the memory system 110 (e.g., TCDRAM). For example, a memory interface block between the host system 105 and the memory system 110 may schedule operations performed by the memory system 110, schedule error control operations, schedule media management operations, schedule test engines, and/or may improve the logic-to-memory I/O of the memory system 110. The use of such an interface block may enable the improvement of the memory system 110 by reducing latency and increasing efficiency of memory accesses, while reducing negative impact on the architecture and design of the host system 105. Additionally, the interface block may be positioned on a die associated with the host system 105, rather than on a die associated with the memory system 110, to further improve performance of the system 100.

In addition to applicability in memory systems as described herein, techniques for scheduling for memory interfaces may be generally implemented to support artificial intelligence applications. As the use of artificial intelligence increases to support machine learning, analytics, decision making, or other related applications, electronic devices that support artificial intelligence applications and processes may be desired. For example, artificial intelligence applications may be associated with accessing relatively large quantities of data for analytical purposes and may benefit from memory devices capable of effectively and efficiently storing relatively large quantities of data or accessing stored data relatively quickly. Implementing the techniques described herein may support artificial intelligence and/or machine learning techniques by improving memory access speeds and efficiency, among other benefits.

FIG. 2 shows an example of a system 200 that supports scheduling for memory in accordance with examples as disclosed herein. The system 200 may include a memory die 210 and a host system die 205 (e.g., GPU die), which may be examples of one of the memory dies 160 and the host system 105 described with reference to FIG. 1. The memory die 210 may include one or more banks 230 of memory cells. The host system die 205 may include one or more processors 215, memory controllers 220 (e.g., MC), and MIB 225, which may be examples of processors, controllers, and interfaces as described with reference to FIG. 1.

In some examples, the system 200 may include the memory die 210, which may include an example of a tightly coupled memory (TCM) architecture such as tightly coupled dynamic random access memory (TCDRAM). As such, the memory die 210 may include the banks 230 which may be accessed by the associated host system dic 205 (e.g., a host system, a processor of a host system) in a single data cycle. For example, banks 230 of the memory die 210 may store time-critical routines and data. In the case that the memory dic 210 may include an example of a TCM architecture, the processors 215 of the host system dic 205 may access the routines and data stored in the banks 230 within one data cycle rather than waiting for various fetch codes and processes external to the system.

In some examples, the system 200 may include the host system die 205. The host system die 205 may include the processors 215, the memory controller 220, and other components which may access and manipulate associated data such that repetitive computations and processes may occur concurrently. For example, the host system die 205 may receive and process graphic-rendering requests sent by an associated host device, and may subsequently perform rapid calculations and other data manipulations such that the requested graphic may be rendered.

The host system die 205 may include one or more of the memory controllers 220. In some cases, the memory controllers 220 may be responsible for various power (e.g., power on, power off), access, and scheduling operations of the memory die 210. For example, the memory controller 220 may control power to various aspects of the host system die 205 such that constraints may be adhered to and performance maximized. The memory controller 220 may also couple the various components of the host system die 205 with each other, with components of the memory die 210, or with another system external to the host system die 205. For example, the memory controller 220 may include a scheduler which may manage requests via a deep queue. That is, the scheduler of the memory controller 220 may receive commands or requests, may store them in the queue (e.g., a FIFO queue), and may issue the requests to various components of the host system die 205 such that latency is minimized. In some examples, the memory controller 220 (e.g., or the memory controller scheduler) may also be responsible for managing read and write aggregation requests, prioritization requests, ordering requests, and other requests.

In some examples, utilization of a tightly coupled architecture as included in the memory die 210 may increase efficiency and high performance for the host system die 205. However, while the memory die 210 may enable efficient memory accesses and other processes due to the close relationship between the host system die 205 and the memory die 210, it may be useful to have and incorporate a memory interface architecture (e.g., the MIB 225) that enables even higher performance.

In some examples, the host system die 205 may include one or more MIBs 225. For example, each of the MIBs 225 may be an interface between the host system die 205 and the memory die 210, and may be located on the host system die 205. The MIBs 225 may allow for improved access operation latency by assisting (e.g., collaborating with) the memory controllers 220 of the host system die 205 on various scheduling operations. For example, the MIBs 225 may schedule operations performed by the system 200, schedule error control operations, schedule media management operations, schedule test engines, and/or may improve logic-to-memory I/O. In some examples, each of the MIBs 225 may include a command arbiter, one or more memory banks and associated short queues (e.g., FIFO queues). As such, each of the MIBs 225 may control timing operations and refresh scheduling associated with each of the banks 230, may assign the banks 230 to perform various commands received from one or more of the memory controller 220, and other operations.

In some examples, each of the MIBs 225 may assist in controlling the flow of commands to and from each of the designated banks 230. For example, each of the banks 230 may be coupled with one or more channels configured to communicate data, C/A, and clock information with the memory die 210. In some cases, each of the banks 230 may be coupled with one or more data pins (e.g., data channels), while one or more of the banks 230 may share C/A pins and clock pins (e.g., C/A channels, clock channels, CLK, RCLK). To enable efficient sharing of these pins, each of the MIBs 225 may control the flow of data and commands over each of the channels between the host system die 205 and the banks 230. For example, one or more of the MIBs 225 may receive a command from the memory controller 220 and may subsequently control, via the memory banks and associated shallow queues (e.g., FIFO queues), and the command arbiter of each of the MIBs 225, which of the MIBs 225 may perform the command. As such, the MIB may enable the improvement of the host system die 205 by reducing latency and increasing efficiency of memory accesses, while reducing negative impact on the architecture and design of the host system.

FIG. 3A shows an example of a device 300-a that supports scheduling for memory in accordance with examples as disclosed herein. The device 300-a may be an example of a device where an ASIC 305 (e.g., another integrated circuit, a die) is coupled with a memory device 310 using an interposer 315 (e.g., a silicon interposer, a glass interposer) and a package substrate 325. The device 300-a may be an example of the system 200 described with reference to FIG. 2. The ASIC 305 may be an example of the host system die 205 and other host devices described with reference to FIGS. 1 and 2. The device 300-a may include the MIBs 335, which may be examples of the MIBs 225 as described with reference to FIG. 2, and may also include a physical interface 340. The memory device 310 may include one or more memory dies 320. The memory dies 320 may each be examples of the memory dies 210 as described with reference to FIG. 2. In some cases, the memory dies 320 may be referred to as memory arrays, arrays of memory cells, or decks of memory cells.

In some examples, for improved power usage and efficiency, the MIBs 335 may be included in a buffer layer 330-a and coupled with the memory device 310 and the ASIC 305-a. For example, the MIBs 335 may be included in the buffer layer 330-a between the memory device 310 and the interposer 315. The MIBs 335 may be coupled with the ASIC 305-a via one or more physical interfaces 340, which may be physically connected via channels through the interposer 315. As described with reference to FIG. 2, the MIBs 335 may assist in controlling the flow of commands and data between the ASIC 305-a and the memory dies 320 by providing temporary storage of and schedules for commands received from the ASIC 305-a and designated for the memory device 310. One or more of the MIBs 335 may receive commands from the ASIC 305-a (e.g., from a memory controller of the ASIC 305-a), may temporarily store the command in a memory bank managed by a shallow queue (e.g., a FIFO queue), and may subsequently determine when the command is to be sent to the memory device and via which channels (e.g., as described with reference to FIG. 2) the command is to be communicated.

FIG. 3B shows an example of a device 300-b that supports scheduling for memory in accordance with examples as disclosed herein. The device 300-b may be an example of a device where an ASIC 305-b is coupled with a memory device 310 over a package substrate 325. The device 300-b may be similar to the device 300-a, except the ASIC 305-b of the device 300-b may be located between a buffer layer 330-b and the package substrate 325. As such, one or more MIBs 335 and one or more physical interfaces 340 may be included within the buffer layer 330-b (e.g., as an interface shim) and may assist in controlling the flow of commands and data between the ASIC 305-b and one or more memory dies 320 of the memory device 310. This interface shim configuration may result in increased bandwidth and increased power efficiency of the device 300-b.

FIG. 3C shows an example of a device 300-c that supports scheduling for memory in accordance with examples as disclosed herein. The device 300-c may be an example of a device where an ASIC 305-c is coupled with a memory device 310 over a package substrate 325. The device 300-c may be similar to the device 300-b, except that one or more MIBs 335 and one or more physical interfaces 340 may be included in a ASIC 305-c. Additionally, the ASIC 305-c of the device 300-b may be located between the memory device 310 and the package substrate 325. As such, the one or more MIBs 335 and the one or more physical interfaces 340 included in the ASIC 305-c may assist in controlling the flow of commands and data between the ASIC 305-c and one or more memory dies 320 of the memory device 310. This configuration of including the MIBs 335 and the physical interfaces 340 into the ASIC 305-c may result in increased bandwidth, power efficiency, decreased latency, and high access speed of the device 300-b.

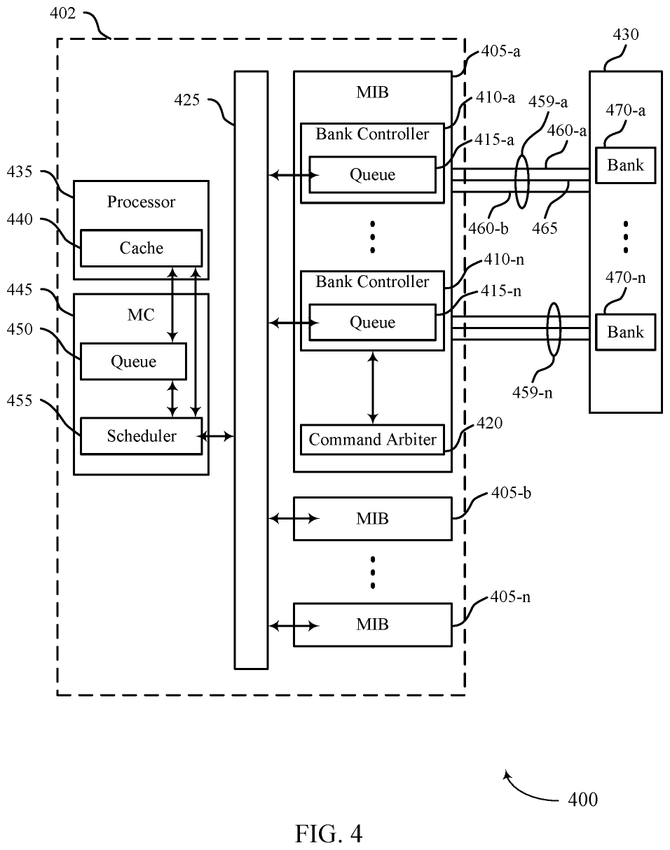

FIG. 4 shows an example of a system 400 that supports scheduling for memory in accordance with examples as disclosed herein. The system 400 may include a host system dic 402 and a memory die 430, which may be examples of the memory die 210 and the host system die 205 described with reference to FIG. 2. The host system die 402 may include one or more processors 435, memory controllers 445 (e.g., MC), and MIBs 405, which may be examples of processors, controllers, and interfaces as described with reference to FIGS. 1-3. Each of the MIBs 405 may include one or more bank controllers 410 and one or more queues 415 (e.g., shallow queue, FIFO queue) which may manage commands received from the memory controller 445 via a physical interface 425. Each of the MIBs 405 may also couple with banks 470 of the memory die 430 via one or more channels 459, which may each include one or more data channels 460 and a C/A channel 465.

The host system die 402 may include the memory controller 445. In some cases, the memory controller 445 may be firmware of the host system die 402 that may be responsible for communicating commands to the memory die 430 (e.g., the banks 470 of the memory die 430). For example, the memory controller 445 may include a queue 450 (e.g., a deep queue, a priority queue) and a scheduler 455, which may temporarily store and manage commands to be sent to the memory die 430. In some examples, the memory controller 445 may store commands in the queue 450 that may be destined for the memory die 430. The scheduler 455 of the memory controller 445 may then determine when each queued command may be buffered from the queue 450 via the physical interface 425.

The system 400 may include one or more of the MIBs 405. Each one of the MIBs 405 may include one or more bank controllers 410. The MIBs 405 may utilize the bank controllers 410 to perform commands using the one or more associated banks 470. The MIBs 405 may each include the command arbiter 420, which may determine which of the banks 470 may be available and may assign one of the available bank controllers 410 to perform the command. The MIBs 405 may also include the queues 415 that may control, in a FIFO method, when the commands stored to the bank controllers 410 are performed.

The system 400 may include one or more of the channels 459 that may each include one or more of the data channels 460 and one or more of the C/A channels 465 coupled with the bank controllers 410, the command arbiter 420, the banks 470, or a combination thereof. For example, the channels 459-a may include the data channel 460-a, the data channel 460-b, and the C/A channel 465 that may be coupled with the MIB 405-a, the bank 470-a, and the bank 470-b (not illustrated). In such an example, the data channel 460-a may be coupled with the bank 470-a and the data channel 460-b may be coupled with the banks 470-b, while the C/A channel 465 may be coupled with (e.g., shared by) both the bank 470-a and the bank 470-b. For example, the data channel 460-a may include four data pins (DQ0-DQ4), and the data channel 460-b (not shown) may include four additional data pins (DQ5-DQ8). In some cases, both the data channel 460-a and the data channel 460-b (e.g., or another data channel pair) may share a clock pin (CLK) and a read clock pin or return clock pin (RCLK). As such, the clock pins (e.g., CLK and RCLK) may be coupled with two of the banks 470 (e.g., the bank 470-a, the bank 470-b), while sets of the other pins of the data channels 460 (e.g., DQ pins, ECC pins) may each be coupled with one of the banks 470.

Each of the MIBs 405 may include one of the command arbiters 420. For example, the command arbiter 420 may perform arbitration operations relating to the banks 470 and the channels 459. For example, the command arbiter 420 may perform channel arbitration operations. As such, the command arbiter 420 may use a round-robin or priority-based arbitration process to determine which command to communicate over the channels 459 and which of the channels 459 to utilize. That is, in the case that the MIB 405-a may receive multiple column or row commands from the host system die 402, the command arbiter 420 may perform a round-robin or priority-based arbitration process to decide which column command or row command may be transmitted to the banks 470 via the channels 459 first (e.g., performed first). Additionally, in the case that both the bank 470-a and the bank 470-b may utilize one or more channels of the channels 459 (e.g., the C/A channel 465, the shared CLK or RCLK pins), the command arbiter 420 may determine which of the memory banks 470 may utilize the channel first. The command arbiter 420 may also perform an arbitration process to decide which of the banks 470 may be available to perform the command (e.g., the column command, the row command). For example, the command arbiter 420 may determine which of the banks 470 to assign the command to by comparing the operation type (e.g., read operations, write operations) of the column of each bank 470 to the operation type of the received command. In some cases, the command arbiter 420 may assign a write command to a bank of the banks 470.

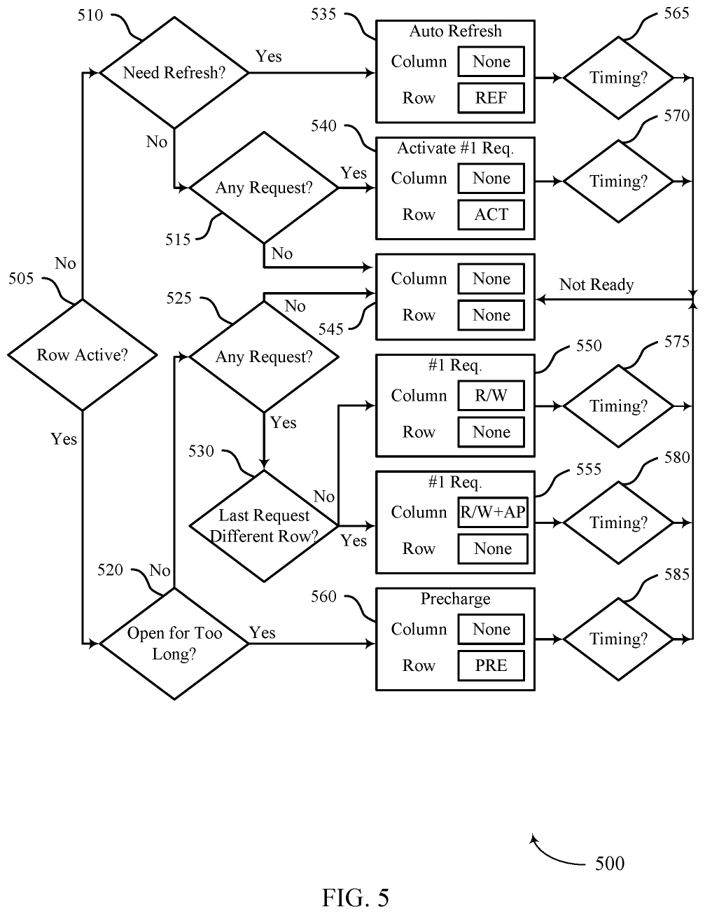

The command arbiter may also perform a pre-bank arbitration process to prepare for incoming commands and pending operations. During the pre-bank arbitration operations, the command arbiter 420 may determine whether each bank of the banks 470 may be prepared to perform a command. For example, during the pre-bank arbitration, the command arbiter 420 may determine that a row of the bank 470-a may be active and prepared to receive a command (e.g., the row may not need to be refreshed or pre-charged), and may subsequently assign the command to the bank 470-a (further described with reference to FIG. 5) while preparing the remaining banks for future commands. In some examples, the pre-bank arbitration process may be an example of a round-robin arbitration process. In the case that the command arbiter may utilize a round-robin arbitration process, the command arbiter may divide the assignment of the command (e.g., data associated with the command) among one or more banks of the banks 470. In some other examples, the pre-bank arbitration process may be an example of a priority-based arbitration process. As such, the command arbiter may compare the priorities of the banks 470 and may assign the command to the bank of the banks 470 that may be characterized by a higher priority or availability. In the case that the banks 470 may not include relative priorities or if the priorities are the same, the command arbiter may default to round-robin arbitration. As a result of this pre-bank arbitration process, the command arbiter 420 may determine which of the banks 470 are prepared to receive commands and then assign the commands (especially write commands) to the various banks.

In some examples, the MIBs 405 may be included in the host system die 402. For example, to improve operation speed, the MIBs 405 may be implemented in the silicon of the host system die 402. As such, the MIBs 405 may assist the memory controller 445 of the host system die 402 in scheduling and performing various commands, which may lead to a decrease in latency and overall system efficiency. For example, the MIBs 405 may be responsible for various access commands regarding the memory die 430, as well as for operations that may be generated by one of the MIBs 405.

In some examples, the MIBs 405 may receive a command from the memory controller 445. For example, the memory controller 445 may transmit an access command to the MIB 405-a. The command arbiter 420 may determine that the received command may be assigned to the bank 470-a. For example, the command arbiter 420, via accessing the C/A channel 465, may determine the bank 470-a to be available to assign the access command to. The MIB 405-a may subsequently store the received command in the queue 415-a associated with the bank controller 410-a and the bank 470-a may perform the command. For example, the access command may be removed from the queue 415-a, communicated to the bank 470-a on the memory die 430 via the channels 459 (e.g., over the C/A channels of the C/A channels 465 and the data channel of the data channels 460 that are associated with the bank 470-a--leaving the other data channels of the channels 459 for other uses).

In some cases, the MIBs 405 may be responsible for performing various media management operations. For example, by including the MIBs 405 on the host system die 402, the MIBs 405 may perform operations that may have been formerly performed by the memory controller 445 or another component of the host system die 402. Examples of the operations the MIBs 405 may be responsible for performing may include DRAM timing operations (as described with reference to FIG. 5), various media management operations, and others. For example, the MIBs 405 may be responsible for row hammer mitigations, refresh operations, error control operations, repair operations, in addition to others. In some cases, the MIBs 405 (e.g., the bank controllers 410) may determine if and when these operations are to be performed, and may also assign one of the banks 470 to perform the determined operation (e.g., the host system die 402 may not send a request or instructions). For example, the MIB 405-a may detect an error caused by a row hammer occurrence or detect a row that has been accessed repeatedly over a time period, and may subsequently perform a row hammer mitigation operation. In other examples, the MIB 405-a may detect an aspect of the memory dic 430 (e.g., a row, a column, a via) in need of repair, and may initiate a repair operation. Additionally, in some examples, the MIBs 405 may be responsible for refreshing each of the associated banks 470 after, and in response to, each of the banks 470 performing an access operation or another type of operation. For example, the MIBs 405 may perform refresh operations during scheduled idle times (e.g., between access operations, between management operations). As such, the MIBs 405 may transmit refresh commands instructing the banks 470 to refresh (e.g., reset) the rows of memory cells of the banks 470. The MIBs 405 may continue to refresh the rows of the banks 470 on schedule and may send refresh commands accordingly.

In systems that use MIBs 405, the host system may not have as much control over the precise time that operations are performed. Such situations may make it harder to ensure that some commands are performed in a timely manner. In some examples, the host system die 402 (e.g., or another host device) may transmit a quality of service (QOS) indicator to one or more of the MIBs 405. The QoS indicator may indicate that one or more commands are priority commands and are to be prioritized over other commands already in the queues for the various banks. For example, the host system die 402 may determine that a QoS operation may be performed on the memory die 430 (e.g., a memory array, cell thereof) and may transmit an indication thereof to the MIB 405-a. The indication of the QoS operation may include an indication to the MIB 405-a to prioritize the command associated with the QoS indicator. In response to the MIB 405-a receiving the indication, the command arbiter 420 may then determine the bank 470-a to be available to perform the QoS operation and may select the MIB 405-a to perform the operation. Subsequently, the MIB 405-a may bypass the rest of the queued commands (e.g., to prioritize the QoS command), and may insert the QoS command at the top of the queue 415-a. The MIB 405-a may then perform the QoS operation.

Incorporating one or more MIBs 405 onto the host system die 402 may result in a reduction of negative impact to the overall host system die 402 (or another host device). For example, implementing one or more of the MIBs 405 may result in faster row hammer mitigation operations, decreased access operation times, and may allow the host system die 402 to focus on other operations. Additionally, the MIBs 405 may allow for the TCDRAM of the MIBs 405 and the memory die 430 to be operable throughout updates and generation changes to the host system die 402 or other host devices. That is, because the use of the MIBs 405 may allow for the sharing of scheduling responsibilities between the host system die 402 and the MIBs 405, the complexity of the host system die 402 may be overall decreased (from the perspective of the host system die 402).

FIG. 5 shows an example of a flowchart 500 that supports scheduling for memory in accordance with examples as disclosed herein. The flowchart 500 may include an example of an arbitration flow which may be made by a MIB while performing operations. The MIB may be an example of the MIBs 225, the MIBs 335, or the MIBs 405, as described with reference to FIGS. 2-4. In some examples, the flowchart 500 may be an example of an arbitration flow that each memory bank of a MIB may perform prior to the MIB marking the memory bank as active. In some cases, arbitration of the MIB may be performed by a command arbiter of the MIB.

Each MIB may perform various types of arbitration. For example, a MIB may perform bank arbitration and channel arbitration (e.g., pseudo channel arbitration). In some examples, one or more MIBs may use a round-robin arbitration process to determine which command to communicate over the shared data channels (as described with reference to FIG. 4). That is, in the case that a MIB may receive multiple column or row commands to be transmitted via the shared channels of the MIB, the MIB may perform a round-robin or priority-based arbitration process to decide which column or row command may be transmitted and performed first. Similarly, one or more of the MIB may perform an arbitration process to decide which of the associated banks may be available to perform operations. For example, a MIB may determine which bank to assign an operation to by comparing the operation type (e.g., read operations, write operations) of the column of the bank to the operation type of the received command. In some cases, the MIB may assign a write operation command to a memory bank that includes continuous write traffic on the associated data channel.

In some examples, each MIB may perform a pre-bank arbitration process. For example, each memory bank of the MIB may perform an arbitration process to prepare for incoming commands and pending operations. As a result of this pre-bank arbitration process, the MIB may determine banks are prepared to receive commands and then assign the commands (especially write commands) to the various banks.

At 505, it may be determined (e.g., by a MIB or other scheduler associated with the memory system) that a row is active. If a row is active, the process may move to 520 and determine if the active row has been open for too long at 520. If the row under question is not active, it may be determined if a refresh operation is to be performed on the active row at 510.

At 510, it may be determined that the active row of the bank is to receive a refresh operation. If it is determined that a refresh on the active row would be helpful, an auto refresh operation may be initiated at 535. If it is determined that a refresh on the active row would not be helpful, it may be determined if any additional request has been received at 525.

At 515, it may be determined that a request may be received. If a request may be received, a request may be pending and the request may be activated at 540. If a request may not be received, the active row may await further operations at 545.

At 520, it may be determined that the active row may be open for too long. If the active row may be open for too long, a precharge operation may be initiated at 560. If the active row may not be open for too long, it may be determined if any request has been received at 525.

At 525, it may be determined that a request may be received. If a request may be received, it may be determined that the previous request performed by the bank included a different row than the active row of the current request at 530. If a request may not be received, the active row may await further operations at 545.

At 530, it may be determined that the previous request performed by the bank may have included a different row than the active row of the current request. If the previous request included a different active row, the request may be performed at 555. If the previous request may not have included a different active row, the request may be performed at 550.

At 535, an auto refresh operation may be initiated. As part of initiating the auto-refresh command, a row command may be determined (e.g., by a MIB or other scheduler associated with the memory system) for the bank. For example, the MIB may determine that a column command may not be used as part of the auto refresh command and that a row command may be used as part of the auto refresh command. It may then be determined at 565 (e.g., by a MIB or other scheduler associated with the memory system) whether the command determined at 535 is ready to be communicated. If so, the command is transmitted to the bank (e.g., by a MIB or other scheduler associated with the memory system). If not, the command may be canceled and the arbitration process may begin again.

At 540, the pending request may be activated. As part of activating the request, a row command may be determined (e.g., by a MIB or other scheduler associated with the memory system) for the bank. For example, the MIB may determine that a column command may not be used as part of the request activation and that a row command may be used as part of the request activation. It may then be determined at 570 (e.g., by a MIB or other scheduler associated with the memory system) whether the command determined at 540 is ready to be communicated. If so, the command is transmitted to the bank (e.g., by a MIB or other scheduler associated with the memory system). If not, the command may be canceled and the arbitration process may begin again.

At 545, the active row may wait for a new request or for a new arbitration process to begin. For example, it may be determined that neither a column command nor a row command may be used during this arbitration process. As such, the active row of the current bank may wait for a new arbitration process to begin.

At 550, the pending request may be performed. As part of performing the request, a column command may be determined (e.g., by a MIB or other scheduler associated with the memory system) for the bank. For example, the MIB may determine that a column command may be used as part of an access operation (e.g., a read operation, a write operation) and that a row command may not be used as part of the operation. It may then be determined at 575 (e.g., by a MIB or other scheduler associated with the memory system) whether the command determined at 550 is ready to be communicated. If so, the command is transmitted to the bank (e.g., by a MIB or other scheduler associated with the memory system). If not, the command may be canceled and the arbitration process may begin again.

At 555, the pending request may be performed. As part of performing the request, a column command may be determined (e.g., by a MIB or other scheduler associated with the memory system) for the bank. For example, the MIB may determine that a column command may be used as part of an access operation (e.g., a read operation, a write operation) and/or an auto-precharge operation and that a row command may not be used as part of the operation. It may then be determined at 580 (e.g., by a MIB or other scheduler associated with the memory system) whether the command determined at 555 is ready to be communicated. If so, the command is transmitted to the bank (e.g., by a MIB or other scheduler associated with the memory system). If not, the command may be canceled and the arbitration process may begin again.

At 560, a precharge operation may be initiated. As part of initiating the precharge command, a row command may be determined (e.g., by a MIB or other scheduler associated with the memory system) for the bank. For example, the MIB may determine that a column command may not be used as part of the precharge command and that a row command may be used as part of the precharge command. It may then be determined at 585 (e.g., by a MIB or other scheduler associated with the memory system) whether the command determined at 560 is ready to be communicated. If so, the command is transmitted to the bank (e.g., by a MIB or other scheduler associated with the memory system). If not, the command may be canceled and the arbitration process may begin again.

FIG. 6 shows a block diagram 600 of a memory system 620 that supports scheduling for memory in accordance with examples as disclosed herein. The memory system 620 may be an example of aspects of a memory system as described with reference to FIGS. 1 through 5. The memory system 620, or various components thereof, may be an example of means for performing various aspects of scheduling for memory as described herein. For example, the memory system 620 may include an interface block component 625, a command component 630, an access component 635, an operation component 640, a buffer component 645, a selection component 650, a detection component 655, or any combination thereof. Each of these components may communicate, directly or indirectly, with one another (e.g., via one or more buses).

The interface block component 625 may be configured as or otherwise support a means for receiving, from a controller, a command to access a volatile memory device that is coupled with the controller, the volatile memory device including a channel coupled with a set of banks including a first bank and a second bank, where the channel includes a first set of data channels dedicated to the first bank, a second set of data channels dedicated to the second bank, and a set of control channels shared by the first bank and the second bank. The command component 630 may be configured as or otherwise support a means for assigning the command to the first bank of the volatile memory device. In some examples, the command component 630 may be configured as or otherwise support a means for determining a sequence of commands communicated over the set of control channels based on the command assigned to the first bank and one or more other commands assigned to the second bank associated with the channel. The access component 635 may be configured as or otherwise support a means for accessing the first bank of the volatile memory device based on determining the sequence of commands.

In some examples, the interface block component 625 may be configured as or otherwise support a means for receiving, from the controller, an indication to prioritize the command over other commands, where assigning the command is based on receiving the indication.

In some examples, the buffer component 645 may be configured as or otherwise support a means for inserting the command at a front of a queue associated with the first bank based on receiving the indication, where determining the sequence of commands is based on inserting the command at the front of the queue.

In some examples, the selection component 650 may be configured as or otherwise support a means for selecting the first bank to perform the command based on receiving the indication, where assigning the first bank is based on selecting the first bank.

In some examples, the operation component 640 may be configured as or otherwise support a means for initiating a media management operation for the volatile memory device based on accessing the first bank.

In some examples, to support initiating the media management operation, the detection component 655 may be configured as or otherwise support a means for detecting a possibility of one or more errors caused by a row hammer event based on accessing the first bank. In some examples, to support initiating the media management operation, the operation component 640 may be configured as or otherwise support a means for initiating a row hammer mitigation operation based on detecting the possibility.

In some examples, to support initiating the media management operation, the operation component 640 may be configured as or otherwise support a means for initiating a refresh operation for the first bank based on accessing the first bank.

In some examples, to support initiating the media management operation, the operation component 640 may be configured as or otherwise support a means for initiating a repair operation to repair a row, a column, or a through-silicon via of the first bank based on accessing the first bank.

In some examples, to support initiating the media management operation, the operation component 640 may be configured as or otherwise support a means for initiating an error control operation for the first bank based on accessing the first bank.

In some examples, the media management operation is initiated without receiving instructions from the controller.

In some examples, the interface block component 625 may be configured as or otherwise support a means for identifying a first performance parameter of the first bank and a second performance parameter of the second bank, where assigning the command to the first bank is based on the first performance parameter and the second performance parameter.

In some examples, to support determining the sequence of commands, the command component 630 may be configured as or otherwise support a means for determining a priority of the command and a duration of pendency of the command, where determining the sequence of commands is based on the priority and the duration of pendency.

In some examples, to support determining the sequence of commands, the command component 630 may be configured as or otherwise support a means for determining a first sequence of commands for the first bank including row commands and columns commands associated with the first sequence of commands. In some examples, to support determining the sequence of commands, the command component 630 may be configured as or otherwise support a means for determining a second sequence of commands for the second bank including row commands and column commands associated with the second sequence of commands, where the sequence of commands communicated over the set of control channels of the channel are based on the row commands and the column commands associated with the first sequence of commands and the row commands and the column commands associated with the second sequence of commands.

In some examples, the interface block component 625 may be configured as or otherwise support a means for determining whether a column command or a row command or both are to be communicated over the set of control channels of the channel as part of performing the command, where determining the sequence of commands is based on determining whether the column command or the row command or both are to be communicated.

FIG. 7 shows a flowchart illustrating a method 700 that supports scheduling for memory in accordance with examples as disclosed herein. The operations of method 700 may be implemented by a memory system or its components as described herein. For example, the operations of method 700 may be performed by a memory system as described with reference to FIGS. 1 through 6. In some examples, a memory system may execute a set of instructions to control the functional elements of the device to perform the described functions. Additionally, or alternatively, the wireless memory system may perform aspects of the described functions using special-purpose hardware.

At 705, the method may include receiving, from a controller, a command to access a volatile memory device that is coupled with the controller, the volatile memory device including a channel coupled with a set of banks including a first bank and a second bank, where the channel includes a first set of data channels dedicated to the first bank, a second set of data channels dedicated to the second bank, and a set of control channels shared by the first bank and the second bank. The operations of 705 may be performed in accordance with examples as disclosed herein. In some examples, the memory system may include one or more MIBs 405 that may receive, from a controller (e.g., a memory controller 445 of the FIG. 4), a command to access a volatile memory device that is coupled with the controller, the volatile memory device including a channel coupled with a set of banks (e.g., the banks 470) including a first bank and a second bank, where the channel includes a first set of data channels dedicated to the first bank, a second set of data channels dedicated to the second bank, and a set of control channels shared by the first bank and the second bank. In some examples, aspects of the operations of 705 may be performed by an interface block component 625 as described with reference to FIG. 6.

At 710, the method may include assigning the command to the first bank of the volatile memory device. The operations of 710 may be performed in accordance with examples as disclosed herein. In some examples, the memory system may include one or more command arbiters 420 that may assign the command to the first bank of the volatile memory device. In some examples, aspects of the operations of 710 may be performed by a command component 630 as described with reference to FIG. 6.

At 715, the method may include determining a sequence of commands communicated over the set of control channels based on the command assigned to the first bank and one or more other commands assigned to the second bank associated with the channel. The operations of 715 may be performed in accordance with examples as disclosed herein. In some examples, a command arbiter of the command arbiters 420 of the memory system may determine a sequence of commands communicated over the set of control channels based on the command assigned to the first bank and one or more other commands assigned to the second bank associated with the channel. In some examples, aspects of the operations of 715 may be performed by a command component 630 as described with reference to FIG. 6.

At 720, the method may include accessing the first bank of the volatile memory device based on determining the sequence of commands. The operations of 720 may be performed in accordance with examples as disclosed herein. In some examples, the memory system may include one or more bank controllers 410 that may access the first bank of the volatile memory device based on determining the sequence of commands. In some examples, aspects of the operations of 720 may be performed by an access component 635 as described with reference to FIG. 6.

In some examples, an apparatus as described herein may perform a method or methods, such as the method 700. The apparatus may include features, circuitry, logic, means, or instructions (e.g., a non-transitory computer-readable medium storing instructions executable by a processor), or any combination thereof for performing the following aspects of the present disclosure:
Aspect 1: A method, apparatus, or non-transitory computer-readable medium including operations, features, circuitry, logic, means, or instructions, or any combination thereof for receiving, from a controller, a command to access a volatile memory device that is coupled with the controller, the volatile memory device including a channel coupled with a set of banks including a first bank and a second bank, where the channel includes a first set of data channels dedicated to the first bank, a second set of data channels dedicated to the second bank, and a set of control channels shared by the first bank and the second bank; assigning the command to the first bank of the volatile memory device; determining a sequence of commands communicated over the set of control channels based on the command assigned to the first bank and one or more other commands assigned to the second bank associated with the channel; and accessing the first bank of the volatile memory device based on determining the sequence of commands.
Aspect 2: The method, apparatus, or non-transitory computer-readable medium of aspect 1, further including operations, features, circuitry, logic, means, or instructions, or any combination thereof for receiving, from the controller, an indication to prioritize the command over other commands, where assigning the command is based on receiving the indication.
Aspect 3: The method, apparatus, or non-transitory computer-readable medium of aspect 2, further including operations, features, circuitry, logic, means, or instructions, or any combination thereof for inserting the command at a front of a queue associated with the first bank based on receiving the indication, where determining the sequence of commands is based on inserting the command at the front of the queue.
Aspect 4: The method, apparatus, or non-transitory computer-readable medium of any of aspects 2 through 3, further including operations, features, circuitry, logic, means, or instructions, or any combination thereof for selecting the first bank to perform the command based on receiving the indication, where assigning the first bank is based on selecting the first bank.
Aspect 5: The method, apparatus, or non-transitory computer-readable medium of any of aspects 1 through 4, further including operations, features, circuitry, logic, means, or instructions, or any combination thereof for initiating a media management operation for the volatile memory device based on accessing the first bank.
Aspect 6: The method, apparatus, or non-transitory computer-readable medium of aspect 5, where initiating the media management operation further includes operations, features, circuitry, logic, means, or instructions, or any combination thereof for detecting a possibility of one or more errors caused by a row hammer event based on accessing the first bank and initiating a row hammer mitigation operation based on detecting the possibility.
Aspect 7: The method, apparatus, or non-transitory computer-readable medium of any of aspects 5 through 6, where initiating the media management operation further includes operations, features, circuitry, logic, means, or instructions, or any combination thereof for initiating a refresh operation for the first bank based on accessing the first bank.
Aspect 8: The method, apparatus, or non-transitory computer-readable medium of any of aspects 5 through 7, where initiating the media management operation further includes operations, features, circuitry, logic, means, or instructions, or any combination thereof for initiating a repair operation to repair a row, a column, or a through-silicon via of the first bank based on accessing the first bank.
Aspect 9: The method, apparatus, or non-transitory computer-readable medium of any of aspects 5 through 8, where initiating the media management operation further includes operations, features, circuitry, logic, means, or instructions, or any combination thereof for initiating an error control operation for the first bank based on accessing the first bank.
Aspect 10: The method, apparatus, or non-transitory computer-readable medium of any of aspects 5 through 9, where the media management operation is initiated without receiving instructions from the controller.
Aspect 11: The method, apparatus, or non-transitory computer-readable medium of any of aspects 1 through 10, further including operations, features, circuitry, logic, means, or instructions, or any combination thereof for identifying a first performance parameter of the first bank and a second performance parameter of the second bank, where assigning the command to the first bank is based on the first performance parameter and the second performance parameter.
Aspect 12: The method, apparatus, or non-transitory computer-readable medium of any of aspects 1 through 11, where determining the sequence of commands further includes operations, features, circuitry, logic, means, or instructions, or any combination thereof for determining a priority of the command and a duration of pendency of the command, where determining the sequence of commands is based on the priority and the duration of pendency.
Aspect 13: The method, apparatus, or non-transitory computer-readable medium of any of aspects 1 through 12, where determining the sequence of commands further includes operations, features, circuitry, logic, means, or instructions, or any combination thereof for determining a first sequence of commands for the first bank including row commands and columns commands associated with the first sequence of commands and determining a second sequence of commands for the second bank including row commands and column commands associated with the second sequence of commands, where the sequence of commands communicated over the set of control channels of the channel are based on the row commands and the column commands associated with the first sequence of commands and the row commands and the column commands associated with the second sequence of commands.
Aspect 14: The method, apparatus, or non-transitory computer-readable medium of any of aspects 1 through 13, further including operations, features, circuitry, logic, means, or instructions, or any combination thereof for determining whether a column command or a row command or both are to be communicated over the set of control channels of the channel as part of performing the command, where determining the sequence of commands is based on determining whether the column command or the row command or both are to be communicated.

It should be noted that the methods described herein describe possible implementations, and that the operations and the steps may be rearranged or otherwise modified and that other implementations are possible. Further, portions from two or more of the methods may be combined.

An apparatus is described. The following provides an overview of aspects of the apparatus as described herein:
Aspect 15: An apparatus, including: a first die; one or more controllers associated with the first die; an interface block coupled with the first die; a second die; and a volatile memory device coupled with the second die, the volatile memory device including: a first bank of memory cells; a second bank of memory cells; and a first channel coupled with the first bank and the second bank, the first channel includes a first set of data channels dedicated to the first bank, a second set of data channels dedicated to the second bank, and a set of control channels shared by the first bank and the second bank; the interface block being configured to schedule access operations for the first bank and the second bank of the volatile memory device based on commands received from the one or more controllers.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (e.g., in conductive contact with, connected with, coupled with) one another if there is any electrical path (e.g., conductive path) between the components that can, at any time, support the flow of signals (e.g., charge, current, voltage) between the components. At any given time, a conductive path between components that are in electronic communication with each other (e.g., in conductive contact with, connected with, coupled with) may be an open circuit or a closed circuit based on the operation of the device that includes the connected components. A conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to condition of moving from an open-circuit relationship between components in which signals are not presently capable of being communicated between the components (e.g., over a conductive path) to a closed-circuit relationship between components in which signals are capable of being communicated between components (e.g., over the conductive path). When a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other when the switch is open. When a controller isolates two components, the controller affects a change that prevents signals from flowing between the components using a conductive path that previously permitted signals to flow.

The terms “layer” and “level” used herein refer to an organization (e.g., a stratum, a sheet) of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, or materials. In some examples, one layer or level may be composed of two or more sublayers or sublevels.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component (e.g., a transistor) discussed herein may represent a field-effect transistor (FET), and may comprise a three-terminal component including a source (e.g., a source terminal), a drain (e.g., a drain terminal), and a gate (e.g., a gate terminal). The terminals may be connected to other electronic components through conductive materials (e.g., metals, alloys). The source and drain may be conductive, and may comprise a doped (e.g., heavily-doped, degenerate) semiconductor region. The source and drain may be separated by a doped (e.g., lightly-doped) semiconductor region or channel. If the channel is n-type (e.g., majority carriers are electrons), then the FET may be referred to as a n-type FET. If the channel is p-type (e.g., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” when a voltage greater than or equal to the transistor's threshold voltage is applied to the transistor gate. The transistor may be “off” or “deactivated” when a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration,” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a dash and a second label that distinguishes among the similar components. If just the first reference label is used in the specification, the description is applicable to any one of the similar components having the same first reference label irrespective of the second reference label.

The functions described herein may be implemented in hardware, software executed by a processor, firmware, or any combination thereof. If implemented in software executed by a processor, the functions may be stored on or transmitted over as one or more instructions (e.g., code) on a computer-readable medium. Other examples and implementations are within the scope of the disclosure and appended claims. For example, due to the nature of software, functions described herein can be implemented using software executed by a processor, hardware, firmware, hardwiring, or combinations of any of these. Features implementing functions may also be physically located at various positions, including being distributed such that portions of functions are implemented at different physical locations.

For example, the various illustrative blocks and modules described in connection with the disclosure herein may be implemented or performed with a processor, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or any type of processor. A processor may also be implemented as a combination of computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

Computer-readable media includes both non-transitory computer storage media and communication media including any medium that facilitates transfer of a computer program from one place to another. A non-transitory storage medium may be any available medium that can be accessed by a computer. By way of example, and not limitation, non-transitory computer-readable media can comprise RAM, ROM, electrically erasable programmable read-only memory (EEPROM), compact disk (CD) ROM or other optical disk storage, magnetic disk storage or other magnetic storage devices, or any other non-transitory medium that can be used to carry or store desired program code means in the form of instructions or data structures and that can be accessed by a computer, or a processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, digital subscriber line (DSL), or wireless technologies such as infrared, radio, and microwave are included in the definition of medium. Disk and disc, as used herein, include CD, laser disc, optical disc, digital versatile disc (DVD), floppy disk and Blu-ray disc where disks usually reproduce data magnetically, while discs reproduce data optically with lasers. Combinations of the above are also included within the scope of computer-readable media.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein, but is to be accorded the broadest scope consistent with the principles and novel features disclosed herein.

What is claimed is:

1. A method, comprising:
receiving, from a controller, a command to access a volatile memory device that is coupled with the controller, the volatile memory device comprising a channel coupled with a set of banks comprising a first bank and a second bank, wherein the channel comprises a first set of data channels dedicated to the first bank, a second set of data channels dedicated to the second bank, and a set of control channels shared by the first bank and the second bank;
assigning the command to the first bank of the volatile memory device;
determining a sequence of commands communicated over the set of control channels based on the command assigned to the first bank and one or more other commands assigned to the second bank associated with the channel; and
accessing the first bank of the volatile memory device based on determining the sequence of commands.

2. The method of claim 1, further comprising:
receiving, from the controller, an indication to prioritize the command over other commands, wherein assigning the command is based on receiving the indication.

3. The method of claim 2, further comprising:
inserting the command at a front of a queue associated with the first bank based on receiving the indication, wherein determining the sequence of commands is based on inserting the command at the front of the queue.

4. The method of claim 2, further comprising:
selecting the first bank to perform the command based on receiving the indication, wherein assigning the first bank is based on selecting the first bank.

5. The method of claim 1, further comprising:
initiating a media management operation for the volatile memory device based on accessing the first bank.

6. The method of claim 5, wherein initiating the media management operation further comprises:
detecting a possibility of one or more errors caused by a row hammer event based on accessing the first bank; and
initiating a row hammer mitigation operation based on detecting the possibility.

7. The method of claim 5, wherein initiating the media management operation further comprises:
initiating a refresh operation for the first bank based on accessing the first bank.

8. The method of claim 5, wherein initiating the media management operation further comprises:
initiating a repair operation to repair a row, a column, or a through-silicon via of the first bank based on accessing the first bank.

9. The method of claim 5, wherein initiating the media management operation further comprises:
initiating an error control operation for the first bank based on accessing the first bank.

10. The method of claim 5, wherein the media management operation is initiated without receiving instructions from the controller.

11. The method of claim 1, further comprising:
identifying a first performance parameter of the first bank and a second performance parameter of the second bank, wherein assigning the command to the first bank is based on the first performance parameter and the second performance parameter.

12. The method of claim 1, wherein determining the sequence of commands further comprises:
determining a priority of the command and a duration of pendency of the command, wherein determining the sequence of commands is based on the priority and the duration of pendency.

13. The method of claim 1, wherein determining the sequence of commands further comprises:
determining a first sequence of commands for the first bank including row commands and columns commands associated with the first sequence of commands; and
determining a second sequence of commands for the second bank including row commands and column commands associated with the second sequence of commands, wherein the sequence of commands communicated over the set of control channels of the channel are based on the row commands and the column commands associated with the first sequence of commands and the row commands and the column commands associated with the second sequence of commands.

14. The method of claim 1, further comprising:
determining whether a column command or a row command or both are to be communicated over the set of control channels of the channel as part of performing the command, wherein determining the sequence of commands is based on determining whether the column command or the row command or both are to be communicated.

15. An apparatus, comprising:
a first die;
one or more controllers associated with the first die;
an interface block coupled with the first die;
a second die; and
a volatile memory device coupled with the second die, the volatile memory device comprising:
a first bank of memory cells;
a second bank of memory cells; and
a first channel coupled with the first bank and the second bank, the first channel comprises a first set of data channels dedicated to the first bank, a second set of data channels dedicated to the second bank, and a set of control channels shared by the first bank and the second bank; and
the interface block being configured to schedule access operations for the first bank and the second bank of the volatile memory device based on commands received from the one or more controllers.

16. The apparatus of claim 15, wherein the interface block is further configured to:
assign a command of the commands received from the one or more controllers to the first bank of the volatile memory device; and
receive, from the one or more controllers, an indication to prioritize the command over other commands.

17. The apparatus of claim 15, wherein the interface block is further configured to:
initiate a media management operation for the volatile memory device.

18. The apparatus of claim 15, wherein the interface block is further configured to:
identify a first performance parameter of the first bank and a second performance parameter of the second bank.

19. The apparatus of claim 15, wherein the interface block is further configured to:
determine a priority of a command received from the one or more controllers and a duration of pendency of the command.

20. A non-transitory computer-readable medium storing code, the code comprising instructions executable by a processor to:
receive, from a controller, a command to access a volatile memory device that is coupled with the controller, the volatile memory device comprising a channel coupled with a set of banks comprising a first bank and a second bank, wherein the channel comprises a first set of data channels dedicated to the first bank, a second set of data channels dedicated to the second bank, and a set of control channels shared by the first bank and the second bank;
assign the command to the first bank of the volatile memory device;
determine a sequence of commands communicated over the set of control channels based on the command assigned to the first bank and one or more other commands assigned to the second bank associated with the channel; and
access the first bank of the volatile memory device based on determining the sequence of commands.
